(19) United States
(12) Patent Application Publication
(10) Pub. No.: US 2008/0083921 A1
(43) Pub. Date: Apr. 10, 2008

(54) SEMICONDUCTOR MEMORY DEVICE AND METHOD OF FORMING THE SAME

(75) Inventors: Takahiro YASUE, Gyeonggi-do (KR); Byeong-Ok CHO, Seoul (KR); Moon-Sook LEE, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/864,103

(22) Filed: Sep. 28, 2007

(30) Foreign Application Priority Data
Oct. 4, 2006 (KR) 10-2006-97503

(51) Int. Cl. H01L 51/30; H01L 51/40

(52) U.S. Cl. 257/40; 438/99; 257/E51.028; 257/E51.029

(57) ABSTRACT

A semiconductor memory device and a method of forming the same are disclosed. The semiconductor memory device may include a first electrode. A monolayer is coupled to the first electrode. An organic memory layer is coupled to the monolayer. A second electrode is coupled to the organic memory layer.

### CROSS-REFERENCE TO RELATED APPLICATIONS

This patent application claims the benefit of foreign priority to Korean Patent Application No. 10-2006-97503, filed on Oct. 4, 2006, the entire contents of which are hereby incorporated by reference.

### BACKGROUND

1. Field of Invention

Embodiments of the present invention relates generally to memory devices and methods of forming the same. More particularly, embodiments of the present invention relate to a semiconductor memory device such as an organic memory device and a method of forming the same.

2. Discussion of the Related Art

Due to the remarkable development of recent information and communication industries, demands for various memory devices have been increased—especially non-volatile memory devices, which are used in portable terminals, various smart cards, electronic cash, digital cameras, memory for game, MP3 players, etc. and require that recorded information not disappear when power is not supplied. Currently, non-volatile memories are formed primarily of inorganic materials like silicon. However, manufacturing processes for a typical inorganic material memory device with high performance and integration are relatively complex, and are difficult to miniaturize.

Therefore, the next generation memory devices with high speed, high capacity, low power consumption, and low price have been actively under development. Organic memory devices using organic materials represent one class of next-generation memory devices. Organic memory devices include organic materials between two electrodes. The organic material may exhibit bistability in a resistance value when an electric signal is applied to the electrodes. That is, the organic memory is a memory capable of writing and reading data 0 and 1 when resistance is reversibly changed through an electric signal in an organic material between two electrodes. This organic memory can still realize non-volatile characteristic of a typical inorganic material memory and can overcome various limitations related to manufacturing properties, cost and integration. Expectation for organic memory has been greatly increased as the next-generation memory.

However, thermal and chemical stability of a high molecular or organic material may not be easily obtained under operational conditions of the organic memory device. Therefore, it is difficult to satisfy the various characteristics that are required by highly integrated memory devices. Additionally, because physical and chemical properties of the organic material are largely different from physical and chemical properties of electrodes, interfacial properties between electrode and organic material may not be satisfactory.

### SUMMARY

Embodiments exemplarily described herein are adapted to provide a reliable organic memory device and a method for forming the same.

One embodiment exemplarily described herein can be characterized as an organic memory device that includes a first electrode, a monolayer coupled to the first electrode, an organic memory layer coupled to the monolayer and a second electrode coupled to the organic memory layer.

Another embodiment exemplarily described herein can be characterized as a method of forming an organic memory device. The method may include forming a first electrode, forming a monolayer that is selectively adsorbed onto and chemically bonded to the first electrode, forming an organic memory layer on the monolayer and forming a second electrode on the organic memory layer.

Yet another embodiment exemplarily described herein can be characterized as a method of forming an organic memory device. The method may include forming a bottom electrode on a substrate, dipping the substrate having the bottom electrode into a solution to form a self-assembled monolayer (SAM) such that the SAM is selectively adsorbed onto and chemically bonded to the bottom electrode, forming an organic memory layer on the SAM and forming a top electrode on the organic memory layer.

### BRIEF DESCRIPTION OF THE FIGURES

The accompanying figures are included to provide a further understanding of the embodiments of the present invention, and are incorporated in and constitute a part of this specification. The drawings illustrate exemplary embodiments described herein and, together with the description, serve to explain principles of the embodiments. In the figures:

FIG. 1 is a view of an organic memory device according to one embodiment;

FIG. 2 is a schematic diagram illustrating an exemplary method of forming SAM according to one embodiment;

FIGS. 3A and 3B are graphs illustrating current-voltage characteristics of organic memory devices without a self-assembled monolayer (SAM) and with a SAM, respectively; and

FIGS. 4A and 4B are graphs illustrating current values measured when the organic devices associated with FIGS. 3A and 3B, respectively, are repeatedly set and reset.

### DETAILED DESCRIPTION

Exemplary embodiments will be described below in more detail with reference to the accompanying drawings. These embodiments may, however, be realized in different forms and should not be constructed as limited to the embodiments set forth herein. Rather, these embodiments are provided so that this disclosure will be thorough and complete, and will fully convey the scope of the present invention to those skilled in the art.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

As used herein, the term ‘substrate’ may refer to a structure based on an arbitrary semiconductor structure. Thus, a substrate may include a silicon-on insulator (SOI), a silicon-on-sapphire (SOS), silicon-germanium, doped or undoped silicon, an epitaxial layer formed through an epitaxial growth technique, or another semiconductor structure. Additionally, the term ‘substrate’ may refer to a glass substrate, a plastic substrate, inorganic material, organic material, or the like or a combination thereof.

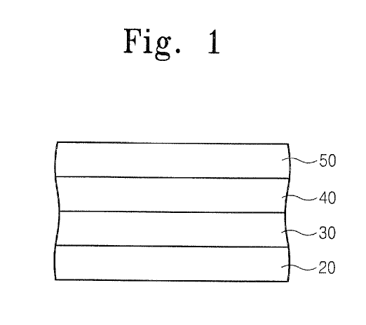

FIG. 1 is a view of an organic memory device according to one embodiment.

Referring to FIG. 1, an organic memory device includes a monolayer 30 and a memory layer 40, which are provided between two electrodes (e.g., a first electrode 20 and a second electrode 50). The memory layer 40 may include an organic material. In one embodiment, the memory layer 40 may be an organic material that can be switchable between at least two resistance states. The memory layer 40 may be controllable through external electric field applied between the first and second electrodes 20 and 50 and/or light irradiation such that it can be switched between a conductive state (e.g., a low resistance state, an on state, or a set state), a non-conductive state (e.g., a high resistance state, an off state or a reset state), or any state having resistance between the conductive state and the non-conductive state.

The memory layer 40 may include polymide, polystyrene, polycarbonate, polymethylmethacrylate, polyolefins, polyesters, polyamide, polyurethanes, polyacetals, polysilicones, polysulfonates, novolacs, polyacetates, polyalkyds, polyamideimides, polysiloxanes, polyarylates, polyarylsulfone, polyethersulfone, polyphenylene sulfide, polyvinyl chloride, polysulfone, polyetherimide, polytetrafluoroethylene, plychlrorotrifluoroethylene, polyvinylidene fluoride, polyvinyl fluoride, polyetherketone, polyether etherketone, polybenzoxazoles, poly(pheylene vinylene), polyfluorene, polythiophene, poly(paraphenylene), polyvinylcarbazole, derivatives thereof, copolymers thereof, or the like or combinations thereof.

The memory layer 40 may include a number of organic layers stacked with a nano-particle layer interposed between the organic layers. Moreover, the memory layer 40 may be formed of a combination of the organic layer and the nano-particle layer. As used herein, a ‘nano-p article layer’ refers to a layer in which nano-particles are arranged. The nano-particle layer may include Al, Au, Ag, Co, Ni, Ge, or the like, a metal alloy thereof, a layered composite thereof, or a combination thereof. In one embodiment, nano-particles may include buckyballs carbon nanotubes, or the like or a combination thereof.

The first and second electrodes 20 and 50 may include metal, metal alloy, conductive metal oxide, conductive metal nitride, metal silicide, conductive polymer, semiconductive material, or the like or a combination thereof. Examples of electrode material may include Ag, Au, Cu, Al, Ti, TiN, TiAlN, Ta, TaN, W, WN, Ir, Pt, Pd, Zr, Rh, Ni, Co, Cr, Sn, Zn, ITO, Li, Mg, K, silicon (e.g., polysilicon) or the like, or an alloy thereof, or a layered composite thereof, a conductive polymer such as conductive polyacetylene, conductive polyaniline, conductive 3,4-ethlenedioxythiophene, or the like, or a combination thereof.

According to one embodiment, the first electrode 20 (also referred to herein as a ‘bottom electrode’) adjacent to the monolayer 30 may, for example, include Ag, Au, Cu, Al, Ti, TiN, TiAlN, Ta, TaN, W, WN, Ir, Pt, Pd, Zr, Rh, Ni, Co, Cr, Sn, Zn, ITO, Li, Mg, K, silicon (e.g., polysilicon), or the like, an alloy thereof, a layered composite thereof or a combination thereof. The second electrode 50 (also referred to herein as a ‘top electrode’) adjacent to the memory layer 40 may, for example, include Ag, Au, Cu, Al, Ti, TiN, TiAlN, Ta, TaN, W, WN, Ir, Pt, Pd, Zr, Rh, Ni, Co, Cr, Sn, Zn, ITO, Li, Mg, K, silicon (e.g., polysilicon), an alloy thereof, a layered composite thereof, a conductive polymer such as conductive polyacetylene, conductive polyaniline, conductive 3,4-ethlenedioxythiophene, or a combination thereof.

Exemplary function(s) of the monolayer 30 may include at least one of the following: improve an interfacial property between the memory layer 40 and the first electrode 20, which have different physical and chemical properties; render an efficient movement of electrons and holes; improve a adhesive property between the memory layer 40 and the first electrode 20; modify the surface property of the first electrode 20; and adjust a work function of the first electrode 20.

The monolayer 30 may be a self-assembled monolayer (SAM) adhered to, and chemically bonded to, the first electrode 20. The SAM 30 may be formed when a precursor of the SAM 30 is voluntarily and chemically adsorbed onto the first electrode 20. For example, the SAM 30 may be formed on the first electrode 20 when a solid surface of the first electrode 20 is immersed or dipped in a solution including precursor molecules of the SAM 30. When a substrate with the first electrode 20 is dipped in the solution including precursor molecules of the SAM 30, the precursor molecules of the SAM 30 that contact the surface of the first electrode 20 are chemically reacted with the first electrode 20 so as to be adsorbed on the surface of the first electrode 20. In another embodiment, the SAM 30 may be chemically adsorbed on the first electrode 20 by using a vapor phase growth method.

Due to immobilization of the precursor molecules through a chemical bonding to the first electrode 20 and/or an attractive interaction between the adjacent precursor molecules, the SAM 30 is mechanically, chemically, and thermodynamically very stable. On the other hand, if there is no SAM, the memory layer 40 may not be chemically adsorbed to the first electrode 20 but may be simply physically adsorbed to the first electrode 20, the adhesion between the memory layer and the first electrode may be defective and an interfacial property therebetween may be deteriorated. However, the bond characteristics between the SAM 30 and the first electrode 20 may be mechanically, chemically, and thermodynamically more stable than the bond property between the memory layer 40 and the first electrode 20, or the bond property (physical adsorption) between the memory layer 40 and the second electrode 50. Moreover, the memory layer 40 is more stably bonded (adsorbed) to the SAM 30 as compared to the first electrode 20 and SAM 30 such that an improved interfacial property exists between the memory 40 and the SAM 30 as compared to an interfacial property between the first electrode 20 and the SAM 30. The SAM 30 may improve an interfacial property and adhesion property between the first electrode 20 and the memory layer 40.

Furthermore, the SAM 30 may decrease Schottky barrier between the first electrode 20 and the memory layer 40. Therefore, carrier transfer between the first electrode 20 and the memory layer 40 can be accelerated. For example, the SAM 30 may change the work function of the first electrode 20 to accelerate the carrier transfer. For example, a precursor of the SAM 30 includes a main chain group (R—) representing important properties of a monolayer, and a reactive functional group forming chemical bond to the electrode. The main chain group (R—) may be a region that contacts the memory layer 40 and may include organic materials, inorganic materials, or the like or a combination thereof. In one embodiment, main chain group (R—) is mainly formed of an organic material for an excellent interfacial property with respect to the memory layer 40. The reactive functional group of the precursor may include organic materials, inorganic materials, or the like or a combination thereof.

The precursor of the SAM 30 may, for example, include an organic acid and halogenide thereof represented in R—CO(OH)ₙX₁₋ₙ (X is halogen element, and n is a natural number); an inorganic acid such as P and S and halogenide thereof represented in R—PO(OH)nX_{2-m, and R—SO}₂(OH)ₙX₁₋ₙ (X is halogen element, n=1, m=0 to 2); a compound with nitrile coordinate substituents represented in R—CN, R—NC, R—NCS; an organic chalcogen represented in R—SH, R—SeH, and R—TeH; an organic dicalcogen compound represented in RS—SR, RSe—SeR, Rte—TeR; an organosilane compound represented in RSiR′ₙX₃₋ₙ (R′═CH₃O and C₂H₅O, X is a halogen element, and n=1 to 3); an organic compound such as alkene, alkyne, alcohol, aldehyde, and alkylhalide; a diazo compound represented in R—N═N—R′ (R′ is aliphatic and aromatic hydrocarbons or its derivative, or the like or a combination thereof. In the above chemical formulas, R may include aliphatic and aromatic hydrocarbons, or their derivatives, and may have a substituent such as B, N, O, F, Si, P, S, Cl, Br, I.

An exemplary precursor of the SAM 30 may include carboxylic acid, acyl halide, aroyl halide, organophosphonic acid, organophosphonate, organo-dihalophosphate, organosulfonic acid, organosulfonyl halide, nitride, isonitrile, thioisocyanide, isocyanide(isonitrile), organothiol, organoselenolate, organotelluolate, disulfide, diselenide, ditelluride, orgagnosilane, alkene, alkyne, alcohol, aldehyde, alkyl halide, a diazo compound, or substituents thereof, or the like.

After the SAM 30 is chemically adsorbed and bonded to the first electrode 20, the memory layer 40 is formed on the SAM 30. In one embodiment, the memory layer 40 may be formed by a spin coating method. After performing spin coating on the memory layer 40, a thermal treatment process may optionally be performed. The second electrode 50 may then be formed on the memory layer 40.

The present inventors have discovered that, within an organic memory device including sequentially stacked first electrode, memory layer and second electrode and not including the SAM, interfacial properties and an adhesive strength are better between the memory layer and the second electrode than interfacial properties and an adhesive strength between the first electrode and the memory layer. Thus, according to one embodiment, the SAM 30 is formed between the first electrode 20 and the memory layer 40 but is not formed between the memory layer 40 and the second electrode 50.

According to another embodiment, however, another SAM may be interposed between the second electrode 50 and the memory layer 40 to achieve an improved interfacial property between the memory layer 40 and the second electrode 50. In such an embodiment, the reactive functional group of the other SAM is adjacent to the second electrode 50 while the main chain group is adjacent to the memory layer 40. The other SAM formed on the memory layer 40 may improve an interfacial property of the memory layer 40. For example, the other SAM may change a work function of the memory layer 40. Therefore, electrons and holes between the second electrode 50 and the memory layer 40 may be transferred more smoothly.

The organic memory device exemplarily described above may be integrated into a substrate by using various methods. For example, the first electrode 20 may be disposed along a first direction over a substrate and the second electrode 50 may be disposed in a second direction over the substrate that is substantially perpendicular to the first direction. The SAM 30 and the memory layer 40 are interposed between the first and second electrodes 20 and 50 such that an organic memory device can be located within a region where the first and second electrodes 20 and 50 cross each other.

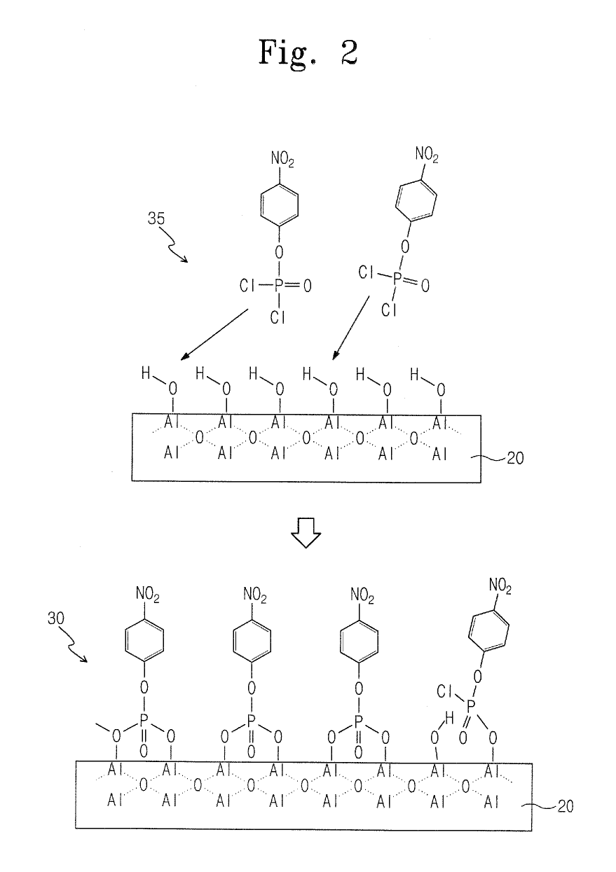

FIG. 2 is a schematic diagram illustrating an exemplary method of forming SAM according to one embodiment.

Referring to FIG. 2, a SAM may be exemplarily formed on a surface of a first electrode 20 (e.g., an aluminum electrode) by using 4-nitrophenyl dichlorophosphate (NPP) precursor molecules. The —PO₂Cl₂ reactive functional group of the NPP precursor molecules 35 has a high affinity with respect to a hydroxyl group (—OH) of the first electrode 20. Accordingly, when the first electrode 20 is immersed (or dipped) into an NPP precursor solution, an organic phosphonic acid is chemically adsorbed onto the aluminum electrode 20 to form SAM 30 through acid-base reaction between the —PO₂Cl₂ reactive functional group and the —OH of the first electrode 20.

### EXPERIMENTAL EXAMPLE

An aluminum first electrode of about 800 Å was formed on a substrate using a vacuum evaporation method. A SAM precursor solution of 0.1 mmol/L, where 4-chlorophenyl dichlorophosphate CBP precursor molecules are dissolved in dichloromethane, was provided. The substrate with the aluminum first electrode was immersed in the solution for 15 min to form SAM on the surface of the aluminum first electrode. After cleansing the resultant structure with IPA, baking was performed for 5 min at 90° C. Polyamic acid, in which fullerene C60 is uniformly dissolved, was provided as a precursor of a polyimide memory layer. After forming the memory layer by spin coating the precursor solution, the solution was removed by baking at 120° C. such that the memory layer precursor layer is formed on the SAM. Curing was performed for 50 min at 300° C. in a nitrogen gas atmosphere to form a polyimide memory layer. An aluminum second electrode of about 800 Å was formed on the polyimide memory layer using a vacuum evaporation method. The process described above represents but one exemplary embodiment of a method of forming an organic memory device according to the principles of the present invention.

### COMPARATIVE EXAMPLE

After forming an aluminum first electrode by using the above method, a SAM was not formed. Rather, a polyimide memory layer was formed on the aluminum first electrode and an aluminum second electrode was formed on the polyimide memory layer to form an organic memory device.

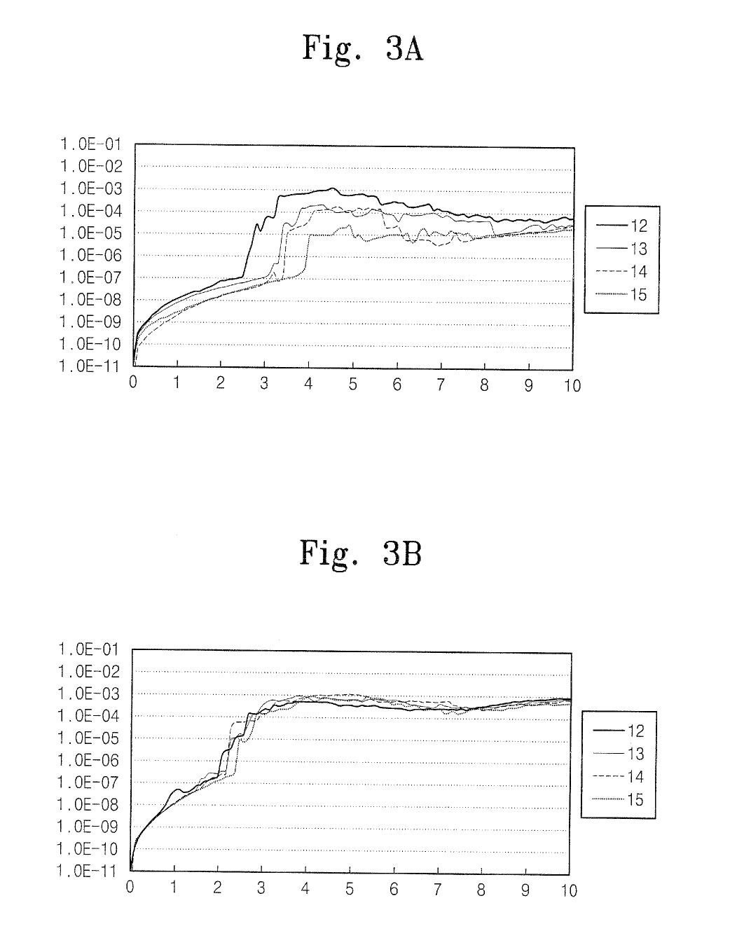

FIGS. 3A and 3B are graphs illustrating current-voltage characteristics of organic memory devices without SAM and with SAM, respectively.

Referring generally to FIGS. 3A and 3B, a voltage of 0 V was applied to the aluminum first electrode, while a sweeping voltage of 0 to 10 V was applied to the aluminum second electrode, of each of the aforementioned Experimental Example and the Comparative Example. Thus, the horizontal axis in the graphs shown in FIGS. 3A and 3B represent the voltage applied to the second electrode of the organic memory device and the vertical axis of the graphs represents measured current values.

Referring to FIG. 3A, when no SAM is present within the organic memory device, the distribution of the current-voltage curve is wide. Additionally, almost no current flows until about 3 V is applied to the aluminum second electrode of the comparative organic memory device, and a current value rises at 4 V. Accordingly, the graph shown in FIG. 3A indicates that a resistance value of the comparative organic memory device is drastically reduced at about 4 V. This means that the comparative organic memory device is set at about 4 V. However, a current value of the comparative organic memory device gradually decreases at voltages above about 4 V. Accordingly, as the applied voltage increases above about 4 V, a resistance value of the comparative organic memory device is reduced. This means that the comparative organic memory device is reset. This property occurs due to characteristics of the polyimide memory layer.

Referring to FIG. 3B, when the SAM is present within the experimental organic memory device, the distribution of the current-voltage curves is relatively narrow. Additionally, a set voltage is about 3 V, which is about 1 V less than the set voltage of the comparative organic memory device.

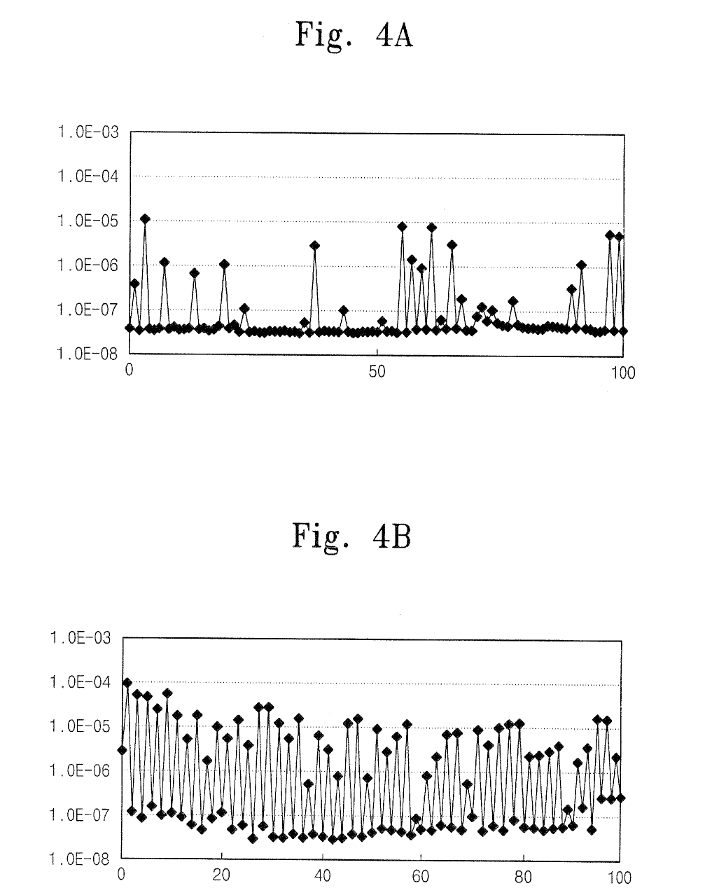

FIGS. 4A and 4B are graphs illustrating current values measured when the organic devices associated with FIGS. 3A and 3B, respectively, are repeatedly set and reset.

Referring generally to FIGS. 4A and 4B, a set pulse (4 V/ms) is used as a set voltage to induce the organic memory device into a set state and a reset pulse (−8 V/ms) is used as a reset voltage to induce the organic memory device into a reset state. Thus, the horizontal axis in the graphs shown in FIGS. 4A and 4B represent the number of times the organic memory device is set and reset and the vertical axis of the graphs represents measured current values.

Referring to FIG. 4A, when no SAM is present within the organic memory device, a difference between a set state and a reset state of the comparative organic memory device becomes indistinguishable as the number of times the comparative organic memory device is set/reset increases. Referring to FIG. 4B, however, the difference between a set state and a reset state of the experimental organic memory device is still distinguishable as the number of times the experimental organic memory device is set/reset increases.

The organic memory device exemplarily described above with respect to the aforementioned embodiments may be used to form logic devices including CPU, a volatile memory such as DRAM, SRAM, etc, an input/output device such as I/O chip, and non-volatile memory such as EEPROM, EPROM, PROM, etc.

The organic memory device exemplarily described above with respect to the aforementioned embodiments may be useful in all devices requiring memory. For example, the organic memory device may be applied to computers, electric appliance, industrial equipment, mobile phones, two-way communication devices, personal portable information terminals, pagers, notebook computers, remote controllers, recorders (video and audio), radios, portable TVs, web viewers, cameras, electronic communication equipment, medical equipment, research and development equipment, transport vehicles, and radar/satellite devices.

According to the embodiments exemplarily described above, an organic memory device can be easily manufactured using a simple method.

According to embodiments exemplarily described above, an operational property of the organic memory device can be improved.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor memory device comprising:
a first electrode;
a monolayer coupled to the first electrode;
an organic memory layer coupled to the monolayer; and
a second electrode coupled to the organic memory layer.

2. The semiconductor memory device of claim 1, wherein the monolayer includes self-assembled monolayer (SAM) that is chemically adsorbed to the first electrode.

3. The semiconductor memory device of claim 2, wherein a precursor of the SAM comprises carboxylic acid, acyl halide, aroyl halide, organophosphonic acid, organophosphonate, organo-dihalophosphate, organosulfonic acid, organosulfonyl halide, nitride, isonitrile, thioisocyanide, isocyanide(isonitrile), organothiol, organoselenolate, organotelluolate, disulfide, diselenide, ditelluride, orgagnosilane, alkene, alkyne, alcohol, aldehyde, alkyl halide, a diazo compound, a low molecular weight compound having a substituent thereof, or a combination thereof.

4. The semiconductor memory device of claim 1, wherein the organic memory layer comprises polymide, polystyrene, polycarbonate, polymethylmethacrylate, polyolefins, polyesters, polyamide, polyurethanes, polyacetals, polysilicones, polysulfonates, novolacs, polyacetates, polyalkyds, polyamideimides, polysiloxanes, polyarylates, polyarylsulfone, polyethersulfone, polyphenylene sulfide, polyvinyl chloride, polysulfone, polyetherimide, polytetrafluoroethylene, plychlrorotrifluoroethylene, polyvinylidene fluoride, polyvinyl fluoride, polyetherketone, polyether etherketone, polybenzoxazoles, poly(pheylene vinylene), polyfluorene, polythiophene, poly(paraphenylene), polyvinylcarbazole, a derivative thereof, a copolymer thereof, or a combination thereof.

5. The semiconductor memory device of claim 1, wherein the first electrode comprises metal, metal alloy, conductive metal oxide, conductive metal nitride, metal silicide, silicon, or a combination thereof.

6. The semiconductor memory device of claim 2, further comprising another SAM interposed between the second electrode and the organic memory layer.

7. The semiconductor memory device of claim 1, wherein the second electrode comprises a conductive polymer.

8. A method of forming a semiconductor memory device, the method comprising:
forming a first electrode;
forming a monolayer that is selectively adsorbed onto and chemically bonded to the first electrode;
forming an organic memory layer on the monolayer; and
forming a second electrode on the organic memory layer.

9. The method of claim 8, wherein forming the monolayer comprises dipping the first electrode into a solution containing a precursor of the monolayer.

10. The method of claim 9, wherein the solution containing the precursor of the monolayer comprises carboxylic acid, acyl halide, aroyl halide, organophosphonic acid, organophosphonate, organo-dihalophosphate, organosulfonic acid, organosulfonyl halide, nitride, isonitrile, thioisocyanide, isocyanide(isonitrile), organothiol, organoselenolate, organotelluolate, disulfide, diselenide, ditelluride, orgagnosilane, alkene, alkyne, alcohol, aldehyde, alkyl halide, a diazo compound, a low molecular weight compound having a substituent thereof, or a combination thereof.

11. The method of claim 8, wherein forming the organic memory layer comprises spin coating a solution containing a precursor of the organic memory layer.

12. The method of claim 11, wherein the solution containing the precursor of the organic memory layer comprises an organic molecule selected from the group consisting of polymide, polystyrene, polycarbonate, polymethylmethacrylate, polyolefins, polyesters, polyamide, polyurethanes, polyacetals, polysilicones, polysulfonates, novolacs, polyacetates, polyalkyds, polyamideimides, polysiloxanes, polyarylates, polyarylsulfone, polyethersulfone, polyphenylene sulfide, polyvinyl chloride, polysulfone, polyetherimide, polytetrafluoroethylene, plychlrorotrifluoroethylene, polyvinylidene fluoride, polyvinyl fluoride, polyetherketone, polyether etherketone, polybenzoxazoles, poly(pheylene vinylene), polyfluorene, polythiophene, poly(paraphenylene), polyvinylcarbazole, a derivative thereof, and a copolymer thereof.

13. The method of claim 8, wherein the first and second electrodes comprise Au, Ag, Cu, Al, Ti, TiN, TiAlN, Ta, TaN, W, WN, Ir, Pt, Pd, Zr, Rh, Ni, Co, Cr, Sn, Zn, ITO, Li, Mg, K, silicon, an alloy thereof, a layered composite thereof or a combination thereof.

14. The method of claim 8, wherein the first electrode comprises Au, Ag, Cu, Al, Ti, TiN, TiAlN, Ta, TaN, W, WN, Ir, Pt, Pd, Zr, Rh, Ni, Co, Cr, Sn, Zn, ITO, Li, Mg, K, silicon, an alloy thereof, a layered composite thereof or a combination thereof and wherein the second electrode comprises polyacetylene, polyaniline, 3,4-ethlenedioxythiophene, or a combination thereof.

15. The method of claim 8, wherein the monolayer is formed using a vapor deposition method in which a monolayer precursor is a source gas.

16. A method of forming a semiconductor memory device, the method comprising:
forming a bottom electrode on a substrate;
dipping the substrate having the bottom electrode into a solution to form a self-assembled monolayer (SAM), the SAM being selectively adsorbed onto and chemically bonded to the bottom electrode;
forming an organic memory layer on the SAM; and
forming a top electrode on the organic memory layer.

17. The method of claim 16, wherein the solution comprises carboxylic acid, acyl halide, aroyl halide, organophosphonic acid, organophosphonate, organo-dihalophosphate, organosulfonic acid, organosulfonyl halide, nitride, isonitrile, thioisocyanide, isocyanide(isonitrile), organothiol, organoselenolate, organotelluolate, disulfide, diselenide, ditelluride, orgagnosilane, alkene, alkyne, alcohol, aldehyde, alkyl halide, a diazo compound, a lower molecular weight compound having a substituent thereof, or a combination thereof.

18. The method of claim 16, wherein the organic memory layer comprises an organic molecule selected from the group consisting of polymide, polystyrene, polycarbonate, polymethylmethacrylate, polyolefins, polyesters, polyamide, polyurethanes, polyacetals, polysilicones, polysulfonates, novolacs, polyacetates, polyalkyds, polyamideimides, polysiloxanes, polyarylates, polyarylsulfone, polyethersulfone, polyphenylene sulfide, polyvinyl chloride, polysulfone, polyetherimide, polytetrafluoroethylene, plychlrorotrifluoroethylene, polyvinylidene fluoride, polyvinyl fluoride, polyetherketone, polyether etherketone, polybenzoxazoles, poly(pheylene vinylene), polyfluorene, polythiophene, poly(paraphenylene), polyvinylcarbazole, a derivative thereof, and a copolymer thereof.

19. The method of claim 16, wherein the bottom electrode and the top electrode comprise Au, Ag, Cu, Al, Ti, TiN, TiAlN, Ta, TaN, W, WN, Ir, Pt, Pd, Zr, Rh, Ni, Co, Cr, Sn, Zn, ITO, Li, Mg, K, silicon, an alloy thereof, a layered composite thereof, or a combination thereof.

20. The method of claim 16, wherein the bottom electrode comprises Au, Ag, Cu, Al, Ti, TiN, TiAlN, Ta, TaN, W, WN, Ir, Pt, Pd, Zr, Rh, Ni, Co, Cr, Sn, Zn, ITO, Li, Mg, K, silicon, an alloy thereof, a layered composite thereof, or a combination thereof and wherein the top electrode comprises polyacetylene, polyaniline, 3,4-ethlenedioxythiophene, or a combination thereof.
